(19) United States
(12) Patent Application Publication
(10) Pub. No.: US 2025/0080012 A1
(43) Pub. Date: Mar. 6, 2025

(54) SUSPENSION MEMBER

(71) Applicant: SOGEFI SUSPENSIONS, GUYANCOURT (FR)

(72) Inventor: Abderrahman OUAKKA, DOUAI (FR)

(21) Appl. No.: 18/815,873

(22) Filed: Aug. 27, 2024

(30) Foreign Application Priority Data
Aug. 31, 2023 (FR) 2309144

(51) Int. Cl. H02N 2/18; B60G 11/14; H02N 2/00; H10N 30/045; H10N 30/50; H10N 30/88

(52) U.S. Cl. CPC H02N 2/186; B60G 11/14; H02N 2/22; H10N 30/045; H10N 30/50; H10N 30/702; H10N 30/883; B60G 2202/12; B60G 2204/40; B60G 2206/42; B60G 2206/70; B60G 2206/80; B60G 2600/00; B60G 2800/162

(57) ABSTRACT

Road vehicle suspension member for converting vibrations and/or mechanical stresses into electricity and a method for producing such a suspension member, the suspension member comprising at least one suspension element or at least one interface element, configured to participate in the fixing of at least one suspension element of the vehicle, and at least one continuous two-dimensional sheet, incorporated in or covering a surface of the suspension element or of the interface element, wherein the at least one two-dimensional sheet comprises at least one piezoelectric layer, comprising piezoelectric fibres collectively orientated in a common direction in such a way as to convert at least some of the vibrations and/or mechanical stresses undergone by the suspension element during operation of the vehicle into electricity, and an electrically conductive collector layer, covering the piezoelectric layer in such a way as to collect the electricity produced by the piezoelectric fibres.

### TECHNICAL FIELD

The present disclosure relates to a suspension member for a motor vehicle, for converting at least some of the vibrations and/or mechanical stresses into electricity, and to a method for producing such a suspension member.

### BACKGROUND

Vehicle suspension elements, including in particular suspension coil springs and anti-roll stabilizer bars, are designed to have an elastic behaviour enabling jolts and vibrations within the vehicle cabin to be reduced. These suspension elements thus undergo significant deformations and vibrations in operation. This is also the case for interface elements intended to fix these suspension elements on the chassis or running gear of the vehicle.

Naturally, these deformations and vibrations normally lead to significant energy losses which are essentially dissipated by friction. It is thus estimated that for a combustion-powered vehicle, 3 to 15% of the energy developed in the engine is thus dissipated in the suspension of the vehicle, the losses even rising to 8 to 39% if only the mechanical energy effectively produced by the engine is considered, in other words if the losses linked to the exhaust (33%) and cooling of the engine (29%) are excluded.

It would therefore be desirable to be able to recover at least some of this energy that is dissipated in the suspension. Several solutions have already been proposed for this purpose in the past, but they are not entirely satisfactory.

For example, certain solutions aim to install an electrical generator at the suspension coil spring or its shock absorber, for example by converting the hydraulic pressure of the shock absorber into torque in a hydraulic motor or by converting the linear displacement of the spring or shock absorber into a rotation using a rack and pinion. However, these solutions require adding heavy and bulky elements, which ultimately penalises the hoped-for energy recovery gain.

Other solutions propose recovering this movement energy by induction, for example by installing a coil, rigidly attached to one end of the spring, around a magnet, rigidly attached to the other end of the spring. However, these solutions are also bulky and difficult to implement in practice.

Finally, other solutions propose installing one or more piezoelectric elements on the suspension element or on an element crushed by the latter. However, to date, the known solutions using piezoelectric elements do not enable a genuinely usable current to be produced. More specifically, in the majority of known configurations, the piezoelectric element is installed at a point and therefore generates only a low potential difference, and only when it is stressed in the right direction. These piezoelectric elements are therefore generally relegated to compression sensor functions without real potential for energy recovery.

There is thus a real need for a suspension member for converting at least some of the vibrations and/or mechanical stresses into electricity, as well as a method for producing such a suspension member, and which are free, at least in part, from the disadvantages inherent in the above-mentioned configurations.

### DISCLOSURE

The present disclosure relates to a suspension member for a road vehicle, comprising
at least one suspension element, having an elastic behaviour in such a way as to act as a suspension spring during operation of the vehicle, or at least one interface element, configured to participate in fixing at least one suspension element of the vehicle having an elastic behaviour in such a way as to act as a suspension spring during operation of the vehicle, and at least one continuous two-dimensional sheet, incorporated in the suspension element or the interface element or covering at least one interface surface of the suspension element or of the interface element, the interface surface being intended to be in contact with another member of the vehicle during operation of the vehicle,
wherein the at least one two-dimensional sheet comprises at least:
a piezoelectric layer, comprising piezoelectric fibres collectively oriented in a common direction in such a way as to convert at least some the vibrations and/or mechanical stresses undergone by the suspension element during operation of the vehicle into electricity, and
an electrically conductive collector layer, covering the piezoelectric layer in such a way as to collect the electricity produced by the piezoelectric fibres.

Through the proposed configuration, in which piezoelectric fibres are distributed and oriented uniformly within a layer of a two-dimensional sheet, it is possible to recover, on average, a satisfactory and usable electric voltage. More specifically, since the piezoelectric fibres are distributed throughout the sheet, the probability that, at any time, a significant number of fibres are stressed in the right direction and therefore generate a potential difference, is greatly increased. The recoverable potential difference and its stability over time, increases all the more with the surface area covered by the sheet, and thus with the number of piezoelectric fibres present. In particular, by disposing such a sheet continuously enclosing piezoelectric fibres over a large surface area, the recovery of various types of stresses is promoted, not being exerted with the same amplitude on the area considered.

In particular, since the collector layer is electrically connected to all of the piezoelectric fibres of the piezoelectric layer, thus forming an upper electrode, it is possible to detect and amplify, depending on the surface area of the sheet and thus the number of piezoelectric fibres, the vibrations which are usually difficult to recover due to their low amplitude.

Furthermore, such a piezoelectric sheet is easy to use and can cover a large surface without increased difficulty. More specifically, the piezoelectric sheet can be prepared beforehand and simply installed during the installation of the suspension member; it can also be directly incorporated in the suspension element or the interface element during its production.

In particular, such a configuration adds very little mass and benefits from a minimal bulk: it is thus possible to install such a piezoelectric sheet in an already existing design of suspension member, without particularly significant adaptation. Such a sheet can even play a role in protecting the suspension element or the interface element and thus replace a protective coating usually provided on this element.

In the present disclosure, a two-dimensional sheet is understood as a sheet extending in two orthogonal directions, a main direction and a transverse direction, the thickness of the two-dimensional sheet being negligible compared with each of these two directions. It is further understood that since the sheet can be flexible, these two directions of extension can be curved. In particular, it is understood that one of these two directions can close on itself and thus form a loop: this is the case, in particular, when the sheet forms a tubular sleeve, the transverse direction of the sheet closing on itself, or when the sheet forms a ring, the main direction of the sheet closing on itself.

In the present disclosure, it is understood that the piezoelectric fibres are collectively oriented in a given direction when, on average, the fibres are oriented in this direction and when not more than 10% of the fibres individually deviate by more than 10° from this direction.

In certain embodiments, the piezoelectric fibres have a length less than 500 μm, optionally less than 70 μm. In particular, these length ranges can reduce the risk of delamination of the layers of the two-dimensional sheet, such a delamination being possible when the piezoelectric fibres are too long.

In certain embodiments, the piezoelectric fibres have a diameter less than 10 μm, optionally less than 700 nm.

In certain embodiments, the piezoelectric fibres comprise fibres of

lead zirconate titanate (PZT), polyvinyl fluoride (PVF), polyvinylidene fluoride (PVDF), polyvinyl chloride (PVC) or barium titanate. For example, the piezoelectric layer may comprise networks of barium titanate nanowires. Optionally, all the piezoelectric fibres are made of the same material.

In certain embodiments, the orientation of the piezoelectric fibres is orthogonal to the collector layer. This orientation can also be orthogonal to the substrate.

In certain embodiments, the thickness of the piezoelectric layer is greater than 70 μm, optionally greater than 500 μm.

In the present disclosure, unless otherwise specified, when a parameter is referred to as greater than or, respectively, less than a given value, here this includes the case where the parameter is equal to the given value.

In certain embodiments, the thickness of the piezoelectric layer is less than 500 μm, optionally less than 70 μm.

5 In certain embodiments, the collector layer comprises phosphate crystals. Such phosphate crystals greatly improve the adhesion of an optional polymer layer on the collector layer.

In certain embodiments, the collector layer comprises at least one metallic element from zinc (Zn), manganese (Mn), copper (Cu) and nickel (Ni). Such a metallic element can promote the electrical conduction of the electric layer.

In certain embodiments, the thickness of the collector layer is greater than 5 μm, optionally greater than 20 μm.

In certain embodiments, the thickness of the collector layer is less than 50 μm, optionally less than 25 μm.

In certain embodiments, the suspension member comprises a first electrically conductive connection cable, electrically connected on the collector layer. In particular, it can be glued on the collector layer.

In certain embodiments, the suspension member comprises a plurality of piezoelectric layers, each comprising piezoelectric fibres collectively oriented in a common direction, an electrically conductive interface layer being inserted between each piezoelectric layer. In particular, all the piezoelectric layers can be identical and oriented in the same direction. In such a case, the collector layer covers the highest piezoelectric layer and the substrate, or an optional base layer, forms the base of the lowest piezoelectric layer. Thus, stacking a plurality of piezoelectric layers in series can increase the voltage produced by the two-dimensional sheet.

In certain embodiments, a piezoelectric layer extends directly from the substrate formed by the suspension element or the interface element, this substrate being electrically conductive. Such a configuration makes it possible for the substrate itself to act as lower electrode connected to the assembly of piezoelectric fibres of the lowest piezoelectric layer.

In certain embodiments, the suspension member comprises a second electrically conductive connection cable, electrically connected on the substrate. In particular, it can be welded or brazed on the substrate.

In certain embodiments, the suspension member comprises an electrically conductive base layer, and a piezoelectric layer extending from the base layer. Such a configuration makes it possible to form a lower electrode connected to the assembly of piezoelectric fibres of the lowest piezoelectric layer, in particular when the substrate is not conductive.

In certain embodiments, the suspension member comprises a second electrically conductive connection cable, electrically connected on the base layer. In particular, it can be glued, welded or brazed on the base layer.

In certain embodiments, the suspension member comprises an electrically insulating protective layer, covering the collector layer. Such a protective layer can electrically insulate the assembly in order to reduce the risk of short-circuit. This protective layer can also protect the suspension element or the interface element against mechanical, physical and/or chemical attacks from its surroundings. In particular, this protective layer can play a protective role against corrosion and/or against impacts such as gravel impacts when the vehicle is moving.

In certain embodiments, the protective layer is made of a polymer material, for example epoxy.

In certain embodiments, the thickness of the protective layer is greater than 120 μm.

In certain embodiments, the two-dimensional sheet takes the form of a sheath surrounding the suspension element or the interface element. Such a sheath can play a further protective role of the suspension element or the interface element.

In certain embodiments, the two-dimensional sheet is deposited, layer by layer, directly on the suspension element or the interface element.

In certain embodiments, the two-dimensional sheet is attached, preferably by gluing, on the suspension element or interface element.

In certain embodiments, the suspension element or interface element is overmoulded on the two-dimensional sheet.

In certain embodiments, the two-dimensional sheet is inserted between two components of the interface element, for example between a frame and an elastomer layer in contact with the suspension element.

In certain embodiments, the suspension element is a coil spring, and the at least one two-dimensional sheet covers at least one portion of the outer surface of the coil spring.

In certain embodiments, the at least one two-dimensional sheet covers at least one end portion of the coil spring, preferably over at least 5 cm, more preferably over at least 10 cm. The end portion of the coil spring is indeed the portion which undergoes the most stresses, in particular because it abuts against a rigid element of the vehicle.

In certain embodiments, the at least one two-dimensional sheet covers at least a central portion of the coil spring, preferably over at least 5 cm, more preferably over at least 10 cm. The active turns of the spring, located remote from the ends and thus having a greater freedom of movement, are the turns which undergo the most vibrations.

In certain embodiments, the at least one two-dimensional sheet covers all of the outer surface of the coil spring.

In certain embodiments, the suspension element is a stabilising bar, and the at least one two-dimensional sheet covers at least one portion of the surface of the stabilising bar which can be held by a bearing of the vehicle.

In certain embodiments, the interface element is a bearing configured to be mounted around a stabilising bar of the vehicle.

In certain embodiments, the at least one two-dimensional sheet covers at least one portion of the inner surface of the bearing, intended to hold the stabilising bar.

In certain embodiments, the at least one two-dimensional sheet is inserted between two components of the bearing, preferably between a frame and an elastomer layer in contact with the stabilising bar.

In certain embodiments, the bearing comprises at least one flange having a cradle portion and two fixing lugs, and the at least one two-dimensional sheet covers at least the cradle portion, and preferably also the inner surface of the fixing lugs.

In certain embodiments, the bearing comprises at least one counter-plate, distinct from the flange and configured to be attached against the bracket, and at least one second two-dimensional sheet covers at least one portion of the inner surface of the counter-plate.

In certain embodiments, the suspension element comprises at least one fixing eyelet, and the at least one two-dimensional sheet covers at least one portion of the inner surface of the fixing eyelet. In such a case, the suspension element can, for example, be a stabilising bar or a leaf spring.

In certain embodiments, the interface element is a bearing configured to be mounted in an eyelet of a suspension element of the vehicle, for example of a leaf spring or of a stabilising bar.

In certain embodiments, the at least one two-dimensional sheet covers at least one portion of the inner surface or outer surface of the bearing.

In certain embodiments, the at least one two-dimensional sheet is inserted between two components of the bearing, preferably between a frame and an elastomer layer.

In certain embodiments, the interface element is a coil spring support element configured to be mounted at one end of a coil spring and to be blocked on a coupling.

In certain embodiments, the at least one two-dimensional sheet covers at least one portion of the outer surface of the support element, intended to be in contact with the coupling.

In certain embodiments, the at least one two-dimensional sheet is inserted between two components of the support element, preferably between a support portion in contact with the coil spring and a base portion in contact with the coupling.

The present disclosure also relates to a method for producing a suspension member for a road vehicle, comprising the following steps: supplying a substrate, intended to form a suspension element, having an elastic behaviour in such a way as to act as a suspension spring during operation of the vehicle, or an interface element, configured to participate in the fixing of at least one suspension element of the vehicle, having an elastic behaviour in such a way as to act as a suspension spring during operation of the vehicle,
depositing a piezoelectric layer, comprising piezoelectric fibres, on the substrate or on a base layer extending over the substrate,
polarising the piezoelectric fibres in such a way as to collectively orient them in a common direction,
depositing an electrically conductive collector layer, on the piezoelectric layer.

Such a method makes it possible to obtain a suspension member as described above, with all the advantages offered by the latter.

In certain embodiments, the depositing of the layer of piezoelectric fibres is carried out by powder coating, spraying or soaking in a fluidised bath.

In certain embodiments, the method comprises a step of shot peening the substrate or the base layer. This shot peening step can take place before and/or after the step of depositing the piezoelectric layer. If carried out before depositing the piezoelectric fibres, the reliefs formed by the shot peening can promote the attachment of the fibres during their deposition; if carried out after depositing the piezoelectric fibres, the impacts caused by the shot peening reinforce the fixing of the fibres on the substrate or the base layer.

In certain embodiments, after the shot peening step, the substrate has a roughness Rt between 5 and 30 μm, preferably between 10 and 20 μm.

In certain embodiments, the depositing of the collector layer is carried out by phosphating, for example in a bath. Such a step may also enable phosphate crystals to be included in the collector layer, which will promote the attachment of an optional polymer layer on the collector layer.

In certain embodiments, the method comprises a step of depositing an electrically insulating protective layer on the piezoelectric layer. Such a protective layer can electrically insulate the assembly, in order to reduce the risk of short-circuit. This protective layer can also protect the suspension element or the interface element against mechanical, physical and/or chemical attacks from its surroundings. In particular, this protective layer can play a protective role against corrosion and/or against impacts such as gravel impacts when the vehicle is moving.

In certain embodiments, the depositing of the protective layer is carried out by powder coating. During such a powder coating step, the piezoelectric fibres are polarised between the substrate and the protective layer: this powder coating step can therefore constitute the polarisation step of the piezoelectric fibres without a separate polarisation step being necessary.

In certain embodiments, the method comprises a connection step, during which a first electrically conductive connection cable is connected on the collector layer, and a second electrically conductive connection cable is connected on the substrate or the base layer. In particular, this connection step can be carried out before the step of depositing the protective layer: in this way, the protective layer can also protect these electrical connections.

In certain embodiments, the method comprises a step of exposing the substrate or the base layer before the connection step. For example, the piezoelectric layer and the collector layer can be scratched in order to expose the substrate or the base layer. This then facilitates the connection step.

The above-mentioned features and advantages, and others, will become apparent on reading the detailed description which follows, of exemplary suspension members and methods for producing such a suspension member. This detailed description refers to the attached drawings.

### BRIEF DESCRIPTION OF THE FIGURES

The attached drawings are schematic and primarily aim to illustrate the principles of the disclosure.

In these drawings, from one figure to another, identical elements

(or parts of elements) are identified by the same reference signs. In addition, elements (or element portions) belonging to the various exemplary embodiments but having an equivalent function, are referenced in the figures by reference numbers incremented by 100, 200, etc.

FIG. 1 is a profile view of a first exemplary suspension member comprising a coil spring.

FIG. 2 is a cross-sectional diagram of this first exemplary suspension member.

FIG. 3 is a micro-photograph of a layer of piezoelectric fibres.

FIG. 4 is a cross-sectional diagram of a second exemplary suspension member.

FIG. 5 is a cross-sectional diagram of a third exemplary suspension member.

### DETAILED DESCRIPTION

In order to make the disclosure more concrete, examples of suspension members and production methods are described in detail below, with reference to the attached drawings. However, the present disclosure is not limited to these examples.

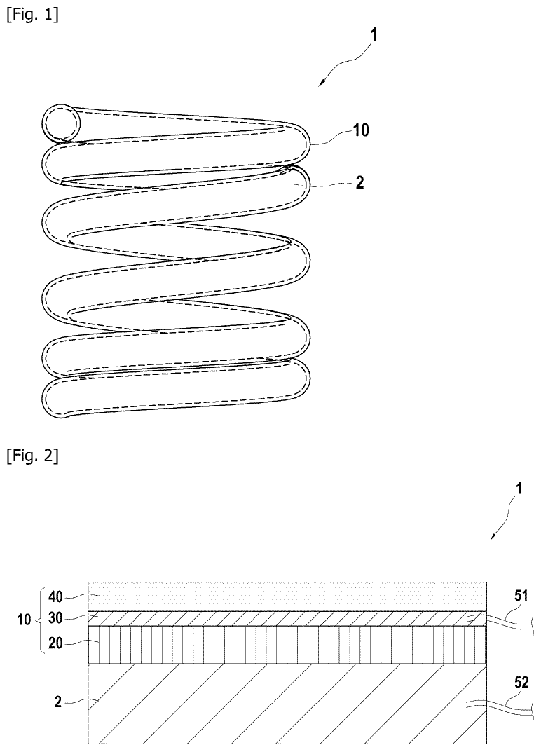

FIG. 1 shows an exemplary suspension member 1 for a vehicle, comprising a coil spring 2 and a piezoelectric sheet 10 in the form of a sheath surrounding the coil spring 2.

FIG. 2 schematically shows this same suspension member 1 in cross-section. The coil spring 2 forms the substrate. The piezoelectric sheet 10 thus comprises a piezoelectric layer 20, deposited on the substrate 2, a collector layer 30 covering the piezoelectric layer 20, and a protective layer 40 covering the collector layer 30. A first connection cable 51 is connected on the collector layer 30 while a second connection cable 52 is connected on the substrate 2.

Here, the coil spring 2 is made of metal, more precisely of steel.

The piezoelectric layer 20 is formed of piezoelectric fibres 21, for example fibres of lead zirconate titanate (PZT), the average length of which is equal to 50 μm here and for which the average diameter here is equal to 500 nm. Therefore, here, the piezoelectric layer 20 has a thickness equal to 70 μm.

The collector layer 30 comprises phosphate crystals as well as metallic elements, in particular zinc, manganese and nickel. The collector layer 30 is therefore electrically conductive. In this example, the thickness of the collector layer 30 is equal to 15 μm.

The protective layer 40 is made of electrically insulating polymer material, for example epoxy. In this example, the thickness of the protective layer 40 is equal to 120 μm.

An exemplary method for producing this suspension member 1 will now be described.

First, a coil spring 2 is supplied or manufactured according to a known method, the coil spring forming the substrate.

The substrate 2 is then shot-peened in order to induce residual internal stresses to increase the service life of the coil spring. At the same time, a roughness Rt of 15 μm on average is imprinted on the surface.

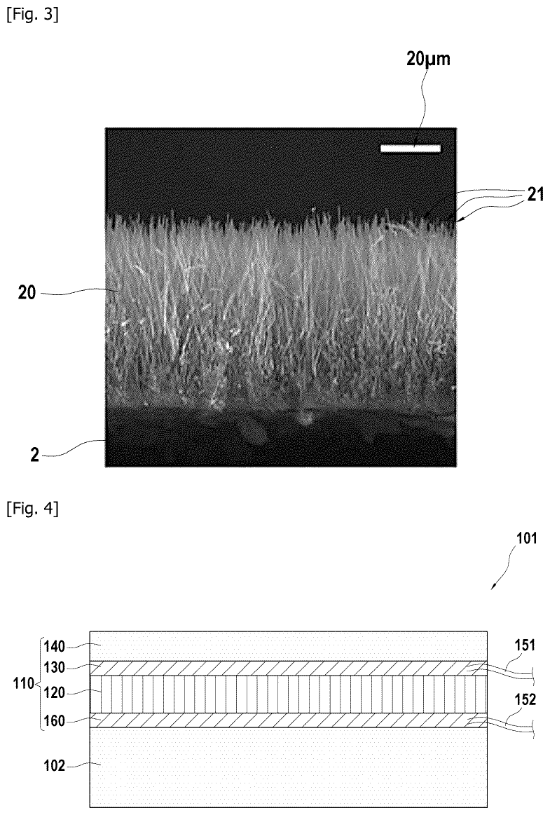

Piezoelectric fibres 21 are then deposited on the substrate 2 by powder coating, in such a way as to form the piezoelectric layer 20. FIG. 3 illustrates such piezoelectric fibres 21 deposited on a substrate 2.

The assembly formed by the substrate 2 and the piezoelectric layer 20 then undergoes a chemical surface treatment step for anti-corrosion protection of the phosphating type, in such a way as to form the conductive collector layer 30. In other examples, this step can also be carried out by a chemical conversion operation in an Oxsilan bath (registered trademark), which generates a very fine layer that is highly adherent to the piezoelectric layer 20.

The first connection cable 51 is then glued on a first portion of the collector layer 30 in order to electrically connect the first connection cable 51 to the collector layer 30. Furthermore, a second portion of the collector layer 30 is scratched away and the portion of the piezoelectric layer 20 located just below, in order to locally bare the substrate 2. The second connection cable 52 can then be welded on the substrate 2 in the area which has been bared in order to electrically connect the second connection cable 52 to the substrate 2.

A powder precursor is then deposited on the collector layer 30 by powder coating. During this powder coating step, the powder precursor is positively charged while the substrate 2 is held at a negative potential.

This potential difference leads to the polarisation of the piezoelectric fibres 21 of the piezoelectric layer 20 which are collectively oriented along the potential gradient, thus orthogonal to the substrate 2 and to the collector layer 30. The assembly is then cured in order to cross-link the precursor powder, thus resulting in the protective layer 40.

Finally, the suspension member 1 is obtained. Therefore, when the suspension member 1 undergoes deformations or vibrations, these deformations or vibrations modify the orientation and/or the length of the piezoelectric fibres 21, which generates an electrical potential difference between the collector layer 30, which constitutes a first electrode, and the substrate 2, which constitutes a second electrode. Since the piezoelectric fibres 21 are all connected in parallel between the collector layer 30 and the substrate 2, the potential difference generated between these two electrodes is significant and can therefore be exploitably recovered by the connection cables 51 and 52. Nevertheless, since by construction this electrical voltage fluctuates strongly over time depending on the amplitude of the stresses and vibrations undergone, it is preferable to connect an electrical rectifier downstream of the piezoelectric sheet 10 in order to smooth the fluctuations in the voltage generated by the piezoelectric sheet 10.

FIG. 4 schematically shows, in cross-section, a second exemplary suspension member 101. In this second example, the substrate 102 is no longer conductive and cannot therefore form an electrode connecting the lower ends of the piezoelectric fibres of the piezoelectric layer 120.

The piezoelectric sheet 110 thus comprises, in addition to a piezoelectric layer 120, a collector layer 130 and a protective layer 140, entirely analogous to those of the first example, an electrically conductive base layer 160 deposited on the substrate 102 and on which the piezoelectric layer 120 is deposited. Thus, this base layer 160 can form a lower electrode connecting the lower ends of the piezoelectric fibres of the piezoelectric layer 120. The second connection cable 152 is then connected on this base layer 160.

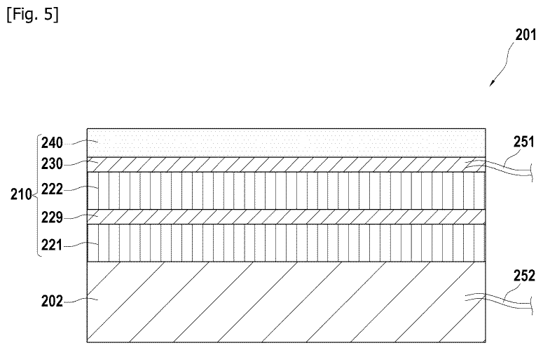

FIG. 5 schematically shows, in cross-section, a third exemplary suspension member 201. This third example is analogous to the first example, except for the fact that here the piezoelectric sheet 210 comprises two piezoelectric layers 221, 222.

Each piezoelectric layer 221, 222 is entirely analogous to the piezoelectric layer 20 of the first example. An electrically conductive intermediate layer 229 is inserted between the two piezoelectric layers 221, 222: the intermediate layer 229 is therefore connected, on the one hand, to the upper ends of the piezoelectric fibres of the lower piezoelectric layer 221, and to the lower ends of the piezoelectric fibres of the upper, second, piezoelectric layer 222. The substrate 202, the collector layer 230 and the protective layer 240 are for their part analogous to those of the first example.

In this way, the piezoelectric sheet 210 has two piezoelectric layers 221, 222 mounted in series, which increases the recoverable voltage between the substrate 202, forming the lower electrode, and the collector layer 230, forming the upper electrode. In this third example, two piezoelectric layers 221, 222 are provided, but a larger number of piezoelectric layers could be provided, inserting an intermediate layer between each piezoelectric layer.

Although the present disclosure has been described with reference to specific exemplary embodiments, it is obvious that modifications and changes can be made to these examples without going beyond the general scope of the present disclosure as defined by the claims. In particular, the individual features of different embodiments illustrated or mentioned can be combined in additional embodiments. Consequently, the description and the drawings should be considered as illustrating rather than limiting.

It is also obvious that all the features described in reference to a method can be transposed, alone or in combination, to a device, and inversely, all the features described in reference to a device can be transposed, alone or in combination, to a method.

1. A road vehicle suspension member, comprising at least one suspension element, having an elastic behaviour in such a way as to act as a suspension spring during operation of the vehicle, or at least one interface element, configured to participate in the fixing of at least one suspension element of the vehicle having an elastic behaviour in such a way as to act as a suspension spring during operation of the vehicle, and
at least one continuous two-dimensional sheet, incorporated in the suspension element or the interface element or covering at least one interface surface of the suspension element or the interface element, said interface surface being intended to be in contact with another member of the vehicle during operation of the vehicle,
wherein the at least one two-dimensional sheet comprises at least:
a piezoelectric layer, comprising piezoelectric fibres collectively oriented in a common direction in such a way as to convert at least some of the vibrations and/or mechanical stresses undergone by the suspension element during operation of the vehicle into electricity, and
an electrically conductive collector layer, covering the piezoelectric layer in such a way as to collect the electricity produced by the piezoelectric fibres.

2. The suspension member according to claim 1, wherein the orientation of the piezoelectric fibres is orthogonal to the collector layer.

3. The suspension member according to claim 1, wherein the collector layer comprises phosphate crystals.

4. The suspension member according to claim 1, comprising a plurality of piezoelectric layers, each comprising piezoelectric fibres collectively oriented in a common direction, an electrically conductive interface layer being inserted between each piezoelectric layer.

5. The suspension member according to claim 1, wherein a piezoelectric layer extends directly from the substrate formed by the suspension element or the interface element, this substrate being electrically conductive.

6. The suspension member according to claim 1, comprising an electrically insulating protective layer covering the collector layer.

7. The suspension member according to claim 1, wherein the two-dimensional sheet takes the form of a sheath surrounding the suspension element or the interface element.

8. A method for producing a road vehicle suspension member, comprising the following steps:
providing a substrate, intended to form a suspension element, having an elastic behaviour in such a way as to act as a suspension spring during operation of the vehicle, or an interface element, configured to participate in the fixing of at least one suspension element of the vehicle, having an elastic behaviour in such a way as to act as a suspension spring during operation of the vehicle,
depositing a piezoelectric layer, comprising piezoelectric fibres, on the substrate or on a base layer extending over the substrate,
polarising the piezoelectric fibres in such a way as to collectively orient them in a common direction,
depositing an electrically conductive collector layer on the piezoelectric layer.

9. The method according to claim 8, wherein the depositing of the piezoelectric layer is carried out by powder coating, spraying or soaking in a fluidised bath.

10. The method according to claim 8, comprising a step of shot peening the substrate or the base layer.

11. The method according to claim 8, wherein the depositing of the collector layer is carried out by phosphating, for example in a bath.

12. The method according to claim 8, comprising a step of depositing an electrically insulating protective layer on the piezoelectric layer,
wherein the depositing of the protective layer is carried out by powder coating.
